(19) United States
(12) Patent Application Publication
(10) Pub. No.: US 2026/0218865 A1
(43) Pub. Date: Jul. 30, 2026

(54) A LIGHT EMITTING DEVICE

(71) Applicant: SIGNIFY HOLDING B.V., EINDHOVEN (NL)

(72) Inventors: JACOBUS PETRUS JOHANNES VAN OS, EINDHOVEN (NL); COEN THEODORUS HUBERTUS FRANCISCUS LIEDERBAUM, OSS (NL); MARC ANDRE DE SAMBER, LOMMEL (BE); NORBERTUS ANTONIUS MARIA SWEEGERS, LIEROP (NL)

(21) Appl. No.: 19/148,775

(22) PCT Filed: Jan. 10, 2024
(86) PCT No.: PCT/EP2024/050453

§ 371 Date: Jul. 17, 2025

(30) Foreign Application Priority Data
Jan. 17, 2023 (EP) 23151901.8

(51) Int. Cl. F21S 4/22; F21V 5/00; F21V 19/00; F21V 29/76; F21Y 103/10; F21Y 103/30; F21Y 107/70; F21Y 115/10; H10H 29/24; H10H 29/80; H10H 29/85; H10H 29/855

(52) U.S. Cl. CPC F21S 4/22; F21V 5/007; F21V 19/005; F21V 29/763; H10H 29/24; H10H 29/8421; H10H 29/855; H10H 29/8582; F21Y 2103/10; F21Y 2103/30; F21Y 2107/70; F21Y 2115/10

(57) ABSTRACT

A light emitting device (1; 100; 101) adapted for, in operation, emitting light emitting device light, the light emitting device (1; 100; 101) comprising an array (2a, 2b) of LED light sources (3a, 3b) adapted for, in operation, emitting LED light, where each LED light source (3a, 3b) comprises an LED package, and an array (4a, 4b) of optical elements (5a, 5b) arranged such that each LED light source (3a, 3b) of the array (2a, 2b) of LED light sources (3a, 3b) is associated with an optical element (5a, 5b) of the array (4a, 4b) of optical elements (5a, 5b), where each optical element (5a, 5b) is configured to convert the LED light of the associated LED light source (3a, 3b) into a beam such that the combined LED light of the LED light sources (3a, 3b) of the array (2a, 2b) of LED light sources (3a, 3b) forming the light emitting device light forms a pixelated array, and where the light emitting device (1; 100; 101) further comprises a flexible substrate (6a, 6b), the array (2a, 2b) of LED light sources (3a, 3b) being arranged on the flexible substrate (6a, 6b), and the array (4a, 4b) of optical elements (5a, 5b) being arranged on the array (2a, 2b) of LED light sources (3a, 3b).

### FIELD OF THE INVENTION

The invention relates to a light emitting device adapted for, in operation, emitting light emitting device light, the light emitting device comprising an array of LED light sources, where each LED light source of the array of LED light sources is adapted for, in operation, emitting LED light, and where each LED light source of the array of LED light sources comprises an LED package, and an array of optical elements, where the array of optical elements is arranged such that each LED light source of the array of LED light sources is associated with an optical element of the array of optical elements.

As used herein the term “array of optical elements” is intended to encompass both an array of individual components and a flexible array of components formed in one piece.

As used herein, the term “flexible substrate” is intended to refer to a substrate that is flexible up to the moment when it is assembled with or mounted on a solid or rigid mounting surface, such as a rigid metal strip.

### BACKGROUND OF THE INVENTION

KR 2012 119729 A discloses a light emitting diode lamp for smoothly radiating heat generated from the lamp. An LED lamp is provided in a rail, and a plurality of LED devices is provided on three sides of the LED lamp in matrix form. A heat radiating plate is provided on a lower side of a substrate. A lens cover covers each LED device, and a connection unit is provided in a housing. A coupling unit of a wire duct is coupled through the connection unit.

The commonly known way to obtain a specific light distribution is to create a specific optical solution in the form of a lens or reflector in combination with a specific light source, such as a COB LED or an assembly of multiple mid-power LEDs. In order to obtain a different light distribution or in case the number of LEDs had decreased because of a luminous efficiency improvement, a new set of optics were to be designed and a mold was to be made, which leads to increased costs and lead time, and kept on stock. This often leads to potential obsolescence and lack of backward compatibility in luminaires.

The invention is based on the insight that driven by advances in TV backlighting industry, where costs are key, a dominant architecture starts to take form for an arrangement of LED components on a MCPCB (Metal Core Printed Circuit Board) substrate or a conventional printed circuit board with copper tracks on PI base material (also known as a LED flexible strip), adhered with double sided tape on an aluminum carrier for heat distribution containing an assembly of mid power LEDs each equipped with a lens having high beam spreading angle of around 140 degrees. In this way by a limited number of LEDs a uniformly lit surface can be created.

However, even with this insight, there is still a desire to provide a light emitting device of the type mentioned by way of introduction, with which the supply chain complexity is decreased, and with which improved opportunities for customization, especially customization of the shape of the light beam emitted by the light emitting device, is created.

### SUMMARY OF THE INVENTION

It is an object of the present invention to overcome this problem, and to provide a light emitting device of the type mentioned by way of introduction, with which the supply chain complexity is decreased.

It is an object of the invention to provide such a light emitting device with which improved opportunities for customization, and especially customization of the shape of the light beam emitted by the light emitting device, is also enabled.

According to a first aspect of the invention, this and other objects are achieved by means of a light emitting device adapted for, in operation, emitting light emitting device light, the light emitting device comprising an array of LED light sources, where each LED light source of the array of LED light sources is adapted for, in operation, emitting LED light, and where each LED light source of the array of LED light sources comprises an LED package, and an array of optical elements, where the array of optical elements is arranged such that each LED light source of the array of LED light sources is associated with an optical element of the array of optical elements, where each optical element of the array of optical elements is configured to convert the LED light of the associated LED light source into a beam such that the combined LED light of the LED light sources of the array of LED light sources forming the light emitting device light forms a pixelated array, and where the light emitting device further comprises a flexible substrate, the array of LED light sources being arranged on the flexible substrate, and the array of optical elements being arranged on the array of LED light sources.

By thus providing a light emitting device with an array of LED light sources in combination with an array of optical elements, for instance both being of the SMD (Surface Mounted Device) type, placed on a semirigid or flexible substrate, a mechanical rearrangement of each of the LEDs in the array for a specific light distribution can be obtained in a way that only requires a change of the mechanical arrangement in order to cover a complete range of light distributions for a particular product family. Furthermore, the use of dedicated optical components, like diffusers, reflectors or specific lens arrays, for a particular application is rendered obsolete. This significantly decreases supply chain complexity as well as creates increased opportunities for customization, especially customization of the shape of the light beam emitted by the light emitting device.

Further, as the array of optical elements in such a construction is small and is arranged on, and thus in the proximity of, the array of LED light sources, the total volume of the light emitting device is significantly smaller compared to the architectures with conventional reflectors or larger lenses, which leads to smaller products which less weight. In other words, the desired light distribution is generated near the LEDs, resulting in that the total light emitting device may be miniaturized, thus reducing the size, costs and environmental impact for housing substantially as well as the reducing the logistics burden for transport. This results less material usage and lower costs for the application.

By further providing that the light emitting device further comprises a flexible substrate, the array of LED light sources being arranged on the flexible substrate, and the array of optical elements being arranged on the array of LED light sources, the thereby achieved flexibility of the substrate allows the array of LED light sources to be mechanically arranged in a variety of shapes. Also, because the LED light sources have limited beam angles determined by the array of optical elements, each shape of the array of LED light sources is for providing a distinct light distribution. Thereby, a light emitting device is provided with which improved opportunities for customization is also enabled.

The LED light sources of the array of LED light sources may be mechanically re-oriented by the flexible substrate being bent in a predetermined direction, by one or more subsets of the LED light sources of the array of LED light sources being oriented in a predetermined direction, or by a combination of both, such as to provide the light emitting device light with a predetermined light pattern.

Thereby, the LED light sources of the array of LED light sources may be rearranged by simple mechanical reorientation in a particularly simple and straight forward manner. Thereby, a light emitting device is obtained with which different light distributions may be created in a particularly simple manner.

One or more of the shape of the flexible substrate bent in a predetermined direction and the orientation of the LED light sources of the array of LED light sources in a predetermined direction may be fixed by any one of foil fixation providing a sealed structure and providing a solid holding device configured to hold the substrate, the array of LED light sources and the array of optical elements.

Thereby, a chosen orientation of the LED light sources of the array of LED light sources, and thus a chosen light distribution, may be fixed in a particularly simple and durable manner during manufacture of the individual light emitting device. This further decreases supply chain complexity as very few components are needed also for the fixation. Furthermore, the construction of a sealed structure additionally leads to the light emitting device being rendered waterproof and particularly suitable for outdoor applications, and also reduces costs on lens mounting.

The sealed structure or the solid holding device may further comprise one or more of at least one first track configured to receive the flexible substrate on which the array of LED light sources is arranged, and a second track configured to receive a driver.

Thereby, a light emitting device is provided which comprises a simple and robust construction. Especially, if both a first and a second track is provided, the light emitting device may be provided with a minimalistic design or construction, which further lowers the manufacturing costs.

The sealed structure or the solid holding device may further comprise at least one first track configured to receive the flexible substrate on which the array of LED light sources is arranged, and a second track configured to receive a driver, where the first track and the second track is arranged on mutually opposite sides of the sealed structure or the solid holding device.

Thereby, a light emitting device is provided with which the driver, when arranged in the second track, is both hidden from view such as to be invisible for the viewer and will not influence the light emitting device light.

The sealed structure or the solid holding device may further comprise one or more air channels configured to provide cooling air to the LED light sources of the array of LED light sources.

The sealed structure or the solid holding device may further comprise one or more heat sink elements configured to provide cooling air to the LED light sources of the array of LED light sources.

Thereby, enhanced cooling is provided for the LED light sources of the array of LED light sources. This in turn prolongs the life-time of the LED light sources of the array of LED light sources.

Furthermore, in case of additional heat sink elements, such elements may in a simple and straight forward manner be provided by laser cutting of plates of a metal.

The sealed structure or the solid holding device may further comprise a support structure, where the flexible substrate is placed on the support structure in such a way that the flexible substrate is in full surface contact with the support structure.

Thereby, a light emitting device is provided which comprises a particularly simple and robust construction.

The foil fixation providing the sealed structure may be provided by any one of sealing, foil sealing, vacuum forming, and molding.

Thereby, the sealed structure may be provided in a particularly simple, fast and cost efficient manner.

The solid holding device may be provided by any one of machining, molding, 3D printing, and a pen arrangement connected to different parts of the substrate.

Thereby, the solid holding device may be provided in a particularly simple, fast and cost efficient manner.

The sealed structure may comprise a first foil being reflective and a second foil being transparent, the first and the second foil each comprising a thickness being less than 0.5 mm.

Thereby, a particularly compact sealed structure may be provided while still obtaining the desired optical characteristics, and particularly light distribution.

The sealed structure may comprise a first foil being reflective and a second foil being transparent, where the first foil is provided with holes arranged in a predetermined pattern, the holes being provided before or during the foil fixation providing the sealed structure.

Thereby, it is ensured that when applying the second foil during the foil fixation, the second foil will be sucked into all edges of the structure such as to provide a smooth and even surface.

The array of optical elements may be an array of lenses.

Thereby, a particularly simple array of optical elements are provided for.

The lenses may for instance be narrow beam generating lenses. Each lens of the array of lenses may comprise a beam angle being in the interval of 30 to 60 degrees FWHM.

Thereby, the resulting light emitting device light is provided as a pixelated array of essentially as many spotlights as there are LED light sources in the array of LED light sources. The total number of lumens of the resulting light emitting device light may be tailored by choosing the number of LED light sources in the array of LED light sources. For instance, if 3000 lm of light emitting device light is desired, around 20-30 LEDs would be needed.

The array of optical elements may be an array of micro-collimators.

Thereby, the resulting light emitting device light is provided as a pixelated array of essentially as many spotlights as there are LED light sources in the array of LED light sources. Additionally, using an array of micro-collimators has the advantage that the low profile advantages relating to lenses may be maintained while added advantageous properties, such as versatile off-axis emission beam formation, good cut-off (and UGR) opportunities, and quite easy assembly as no optical contact towards the LED package is required may be achieved.

Each micro-collimator of the array of micro-collimators may comprise a single micro-collimator or a combination of two or more micro-collimators.

Using a single micro-collimator for each LED package results in a high degree of flexibility even after mounting LDS and micro-collimators on the flexible structure. Combined collimators results in a larger rigid area on the light emitting device.

The array of LED light sources may comprise one or more of mid-power LEDs and COB LEDs.

The array of LED light sources may be configured to form a LED strip.

The array of LED light sources may comprise more than 6 LED light sources, more than 12 LED light sources, more than 20 LED light sources or between 20 and 30 LED light sources.

The invention further relates to a luminaire comprising at least one light emitting device according to the invention, where the LED light sources of the array of LED light sources of the at least one light emitting device are mechanically re-oriented by one or both of the following: the flexible substrate is bent in a predetermined direction, and one or more subsets of the LED light sources of the array of LED light sources are oriented in a predetermined direction, such as to provide the light emitting device light with a predetermined light pattern.

The invention further relates to a luminaire comprising at least two light emitting devices according to the invention, where the LED light sources of the array of LED light sources of at least one of the at least two light emitting devices are mechanically re-oriented by one or both of the following: the flexible substrate is bent in a predetermined direction, and one or more subsets of the LED light sources of the array of LED light sources are oriented in a predetermined direction, such as to provide the light emitting device light with a predetermined light pattern, and a track driver arranged centrally between the at least two light emitting devices.

The luminaire according to the invention may be configured to be used in indoor applications or in outdoor applications.

The luminaire according to the invention may be configured to be used in a lighting application that requires a specific light distribution.

The luminaire according to the invention may be a low profile/low height ceiling luminaire, a downlight, a linear luminaire, a troffer, and an outdoor luminaire.

It is noted that the invention relates to all possible combinations of features recited in the claims.

### BRIEF DESCRIPTION OF THE DRAWINGS

This and other aspects of the present invention will now be described in more detail, with reference to the appended drawings showing embodiment(s) of the invention.

FIG. 1 shows an exploded view of a light emitting device according to the invention and comprising an array of LED light sources, an array of optical elements, a flexible substrate and a solid holding device configured to hold the substrate, the array of LED light sources and the array of optical elements.

FIG. 2 shows a perspective view of the light emitting device according to claim 1 in an assembled condition.

FIG. 3 shows an exploded view of another light emitting device according to the invention.

FIG. 4A-F shows steps of a method of manufacturing a light emitting device according to the invention and as shown in FIG. 3 by foil fixation.

FIG. 5A-B shows additional steps of a method according to FIG. 4A-F.

FIG. 6 shows a perspective view of another solid holding device of a light emitting device according to the invention.

FIGS. 7 and 8 show perspective views of yet another solid holding device of a light emitting device according to the invention without and with an array of LED light sources and an array of optical elements mounted thereon, respectively.

FIG. 9 shows a cross-sectional side view of another light emitting device according to the invention.

FIGS. 10 and 11 show a top view and a perspective view, respectively, of the light emitting device according to FIG. 9.

FIGS. 12 and 13 show cross-sectional side views of two different luminaires comprising light emitting devices according to the invention.

FIG. 14 shows a cross-sectional side view of another luminaire comprising light emitting devices according to the invention and further comprising a central track driver.

As illustrated in the figures, the sizes of layers and regions are exaggerated for illustrative purposes and, thus, are provided to illustrate the general structures of embodiments of the present invention. Like reference numerals refer to like elements throughout.

### DETAILED DESCRIPTION

The present invention will now be described more fully hereinafter with reference to the accompanying drawings, in which currently preferred embodiments of the invention are shown. This invention may, however, be embodied in many different forms and should not be construed as limited to the embodiments set forth herein; rather, these embodiments are provided for thoroughness and completeness, and fully convey the scope of the invention to the skilled person.

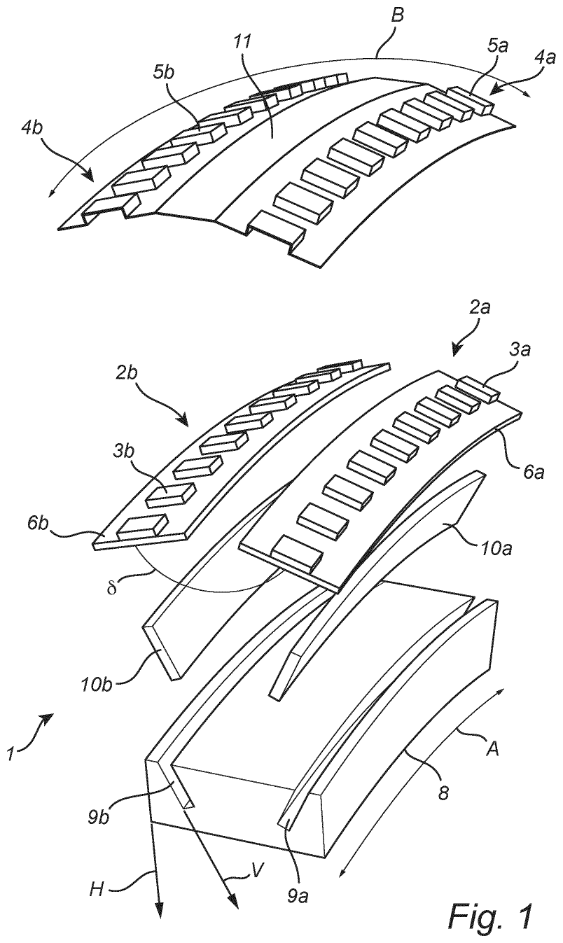

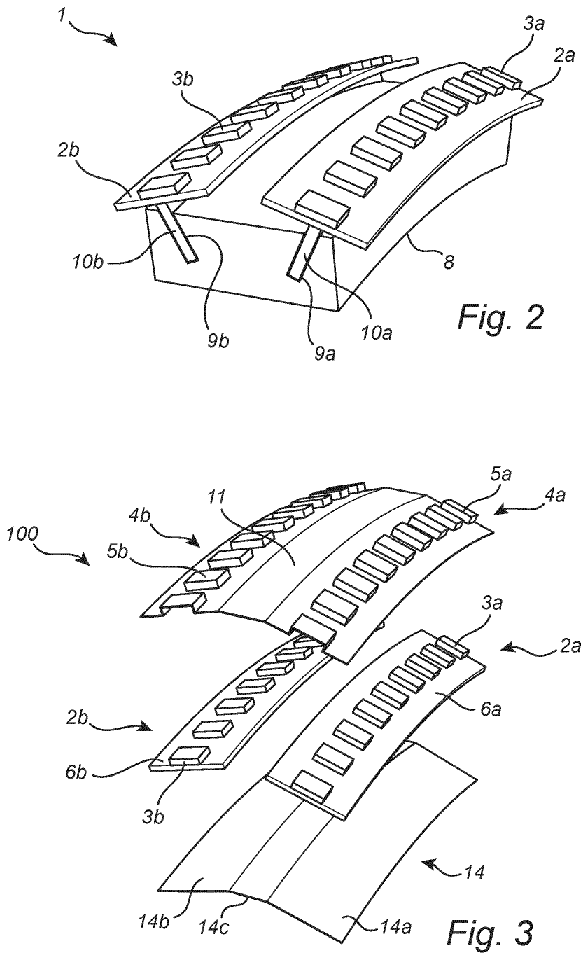

FIG. 1 shows an exploded view of a light emitting device 1 according to the invention. FIG. 2 shows the light emitting device 1 in an assembled condition. Generally, and irrespective of the embodiment, the light emitting device 1 comprises an array 2a, 2b of LED light sources 3a, 3b arranged on a flexible substrate 6a, 6b and an array 4a, 4b of optical elements 5a, 5b. For the sake of simplicity, the array 4a, 4b of optical elements 5a, 5b is only shown in FIG. 1. Generally, and irrespective of the embodiment, the light emitting device 1 is adapted for, in operation, emitting light emitting device light.

In the embodiment shown in FIG. 1, the light emitting device 1 further comprises a solid holding device 8 configured to hold and fix in position the flexible substrate 6a, 6b, the array 2a, 2b of LED light sources 3a, 3b and the array 4a, 4b of optical elements 5a, 5b.

Generally, and irrespective of the embodiment, as used herein, the term “flexible substrate” is intended to refer to a substrate that is flexible up to the moment when it is assembled with or mounted on a solid or rigid mounting surface, such as a rigid metal strip. More particularly, the flexible substrate 6a, 6b, and thereby the light emitting device 1, is bendable before mounting, but is not required to be flexible, or stretchable, or foldable after mounting, on a solid or rigid mounting surface. This enables the LED light sources 3a, 3b of the array 2a, 2b of LED light sources to be mechanically re-oriented by bending the flexible substrate 6a, 6b in a predetermined direction, and/or orienting one or more subsets of the LED light sources 3a, 3b of the array 2a, 2b of LED light sources in a predetermined direction, such as to provide the light emitting device light emitted by the light emitting device 1 with a predetermined light pattern.

Generally, and irrespective of the embodiment, each LED light source 3a, 3b of the array 2a, 2b of LED light sources is adapted for, in operation, emitting LED light. Each LED light source 3a, 3b of the array of LED light sources comprises an LED package.

The LED light sources 3a, 3b may be any suitable type of LED light sources. For instance, the LED light sources 3a, 3b may be mid power LEDs (for instance emitting around 100-150 lm per LED package). Alternatively, the LED light sources 3a, 3b may be COB LEDs. The array 2a, 2b of LED light sources 3a, 3b may be configured to form any suitable or desired shape. For instance, the array 2a, 2b of LED light sources 3a, 3b may be configured to form a LED strip.

The combined LED light source light of all LED light sources 3a, 3b forms the light emitting device light. The total amount of lumens of light emitting device light emitted by the light emitting device 1 may be tailored by adding (or removing) a relevant number of LED light sources 3a, 3b. For instance, for a light emitting device 1 emitting 3000 lm of light emitting device light, an array 2a, 2b with around 20-30 LED light sources 3a, 3b would be needed.

Generally, and irrespective of the embodiment, the array 4a, 4b of optical elements 5a, 5b is arranged such that each LED light source 3a, 3b of the array 2a, 2b of LED light sources is associated with an optical element 5a, 5b of the array 4a, 4b of optical elements. Each optical element 5a, 5b of the array 4a, 4b of optical elements is further configured to convert the LED light of the associated LED light source 3a, 3b into a beam such that the combined LED light of the LED light sources 3a, 3b of the array 2a, 2b of LEDs forming the light emitting device light forms a pixelated array. In the embodiment shown in FIGS. 1 and 2 the arrays 4a, 4b of optical elements 5a, 5b are connected by a flexible connection section 11, such as a foil. In other embodiments the connection section 11 may be omitted.

Thus, each LED light source 3a, 3b is equipped by an optical element 5a, 5b. The optical elements 5a, 5b may generally be lenses, as is the case in the embodiment of FIGS. 1 and 2, or micro-collimators, as is the case for the embodiment shown in FIGS. 9-11 and described further below. The optical elements 5a, 5b may for instance be lenses each having a limited beam angle of around 30-60 degrees FWHM.

In an alternative, the array 4a, 4b of optical elements 5a, 5b is arranged such that each sub-group of LED light source 3a, 3b of the array 2a, 2b of LED light sources is associated with an optical element 5a, 5b of the array 4a, 4b of optical elements. In this case the number of optical elements 5a, 5b in the array 4a, 4b of optical elements 5a, 5b is smaller than the number of LED light sources 3a, 3b in the array 2a, 2b of LED light sources 3a, 3b. For instance, a sub-group of two, three or four LED light sources 3a, 3b may be associated with each optical element 5a, 5b of the array 4a, 4b of optical elements. Also, different numbers of LED light sources 3a, 3b may be associated with different optical elements 5a, 5b of the array 4a, 4b of optical elements 4a, 4b.

The array 2a, 2b of LED light sources 3a, 3b is arranged on the flexible substrate 6a, 6b, and the array 4a, 4b of optical elements 5a, 5b is arranged on the array 2a, 2b of LED light sources 3a, 3b.

It is noted that in the embodiment shown in FIGS. 1 and 2, there is provided two arrays 2a, 2b of LED light sources 3a, 3b as well as two arrays 4a, 4b of optical elements 5a, 5b. In other embodiments, the number of arrays 2a, 2b of LED light sources and of arrays 4a, 4b of optical elements, respectively may be different from two, such as one or three or more than three.

In the embodiment shown in FIGS. 1 and 2, the light emitting device 1 further comprises a solid holding device 8 for holding and fixing in position the flexible substrate 6a, 6b, the array 4a, 4b of optical elements 5a, 5b and the array 2a, 2b of LED light sources 3a, 3b. The holding device 8 comprises two slits 9a, 9b configured to receive a respective heat sink element 10a, 10b, on which the respective substrate 6a, 6b is arranged.

The solid holding device 8 is configured to ensure that the flexible substrate 6a, 6b is bent in a predetermined direction and is fixed in that position when mounted on the solid holding device 8. This may be achieved by providing the holding device 8 with a suitable surface curvature as indicated by the arrow A in FIG. 1. The surface curvature in the direction indicated by the arrow A may for instance be 500 mm. The solid holding device 8 is further configured to ensure that one or more of the LED light sources 3a, 3b of the array 2a, 2b of LED light sources 3a, 3b are oriented in a predetermined direction and is fixed in that orientation. This may likewise be achieved by providing the holding device 8 with a suitable surface curvature. As shown in FIGS. 1 and 2, it may also be achieved by providing the slits 9a, 9b to extend in a direction V being angled with respect to the height direction H of the holding device 8. This will provide the assembled light emitting device 1 with a surface curvature as indicated by the arrow B in FIG. 1. The direction V, and thus surface curvature as indicated by the arrow B, may be chosen such that an angle of −30°, −60°, 30° or 60° between the plane of the flexible substrate 6a, 6b of neighboring arrays 2a, 2b of LED light sources 3a, 3b is obtained. The light distribution may be defined by the surface curvature(s). In the present example the flexible substrate 6a, 6b is only bent in one direction. In most cases, a convex shaped flexible substrate 6a, 6b and thus LED light source array 2a, 2b is suitable, although concave configurations will lead to a focus point designed construction if required. An example of a suitable radius in the convex construction is 500 mm. Concave and convex systems can be designed in both directions A and B.

The light emitting device 1 is in this embodiment assembled, and the shape of the flexible substrate 6a, 6b bent in a predetermined direction and/or the orientation of the LED light sources 3a, 3b of the array 2a, 2b of LED light sources 3a, 3b in a predetermined direction is fixed, by means of the holding device 8 as follows.

First, the heat sink elements 10a, 10b are placed in the slits 9a, 9b of the holding device 8, then the flexible substrate 6a, 6b, the array 4a, 4b of optical elements 5a, 5b and the array 2a, 2b of LED light sources 3a, 3b are arranged on the heat sink element 10a, 10b. Alternatively, the flexible substrate 6a, 6b, the array 4a, 4b of optical elements 5a, 5b and the array 2a, 2b of LED light sources 3a, 3b may be arranged on the heat sink elements 10a, 10b, before the heat sink elements 10a, 10b are arranged in the slits 9a, 9b of the holding device 8. Also, the assembly comprising the flexible substrate 6a, 6b, the array 4a, 4b of optical elements 5a, 5b and the array 2a, 2b of LED light sources 3a, 3b may be formed first, and the assembly may then be arranged on the heat sink elements 10a, 10b either before or after they have been arranged in the slits 9a, 9b of the holding device 8. Alternatively, the assembly comprising the flexible substrate 6a, 6b, the array 4a, 4b of optical elements 5a, 5b and the array 2a, 2b of LED light sources 3a, 3b may be formed on the heat sink elements 10a, 10b either before or after they have been arranged in the slits 9a, 9b of the holding device 8.

For instance, the heat sink elements 10a, 10b may be made of metal plates cut out for instance by laser cutting and attached to the flexible substrate 6a, 6b. The holding device 8 may for instance be 3D printed and is configured to keep all the parts together.

FIG. 3 shows an exploded view of a light emitting device 100 according to another embodiment of the invention. The light emitting device 100 differs from that described above in relation to FIGS. 1 and 2 in virtue of the following features.

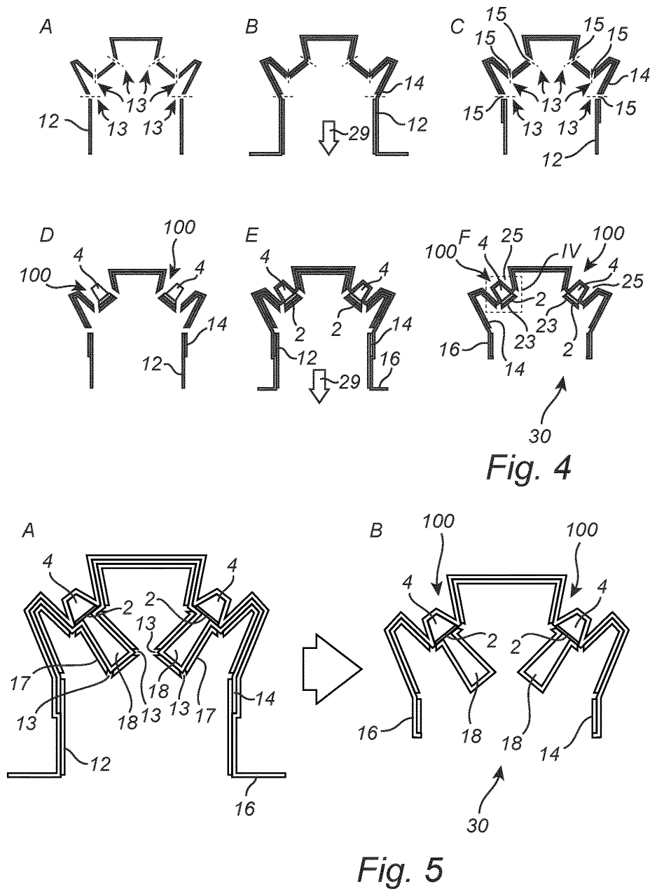

The light emitting device 100 comprises, instead of the solid holding device 8, a first foil 14 and a second foil 16. The second foil 16 is not shown in FIG. 3 for the sake of simplicity, see instead for instance FIG. 4F. The first foil 14 comprises in the embodiment shown three sections 14a, 14b and 14c. Sections 14a and 14b are adapted to receive the respective substrate 6a and 6b. Section 14c is a connection section connecting sections 14a and 14b. Furthermore, the arrays 4a, 4b of optical elements 5a, 5b comprise a connection section 11 such that the arrays 4a, 4b of optical elements 5a, 5b are in one piece.

In the assembled condition of the light emitting device 100—see FIG. 4F—the first foil is arranged underneath the flexible substrate 6a, 6b, while the second foil 16 is arranged on top of the arrays 4a, 4b of optical elements 5a, 5b.

The light emitting device 100 is in this way adapted for being assembled, and the shape of the flexible substrate 6a, 6b bent in a predetermined direction and/or the orientation of the LED light sources 3a, 3b of the array 2a, 2b of LED light sources 3a, 3b in a predetermined direction for being fixed, by means of foil fixation.

FIG. 4A-F illustrate steps of a method of manufacturing a light emitting device, such as the light emitting device 100 of FIG. 3, according to the invention by foil fixation.

In a first step, a hollow jig 12 or form is prepared. In FIG. 4A the schematic cross section of an example of such a jig 12 is shown. In areas of undercut, holes 13 are made in the jig 12 such as to enable sucking a layer of first foil 14 into the edges. In a next step, as illustrated in FIG. 4B, the first layer of foil 14 is vacuum formed onto the jig 12 by applying a vacuum from below (arrow 29). The first foil 14 can consist of a layer of materials where for example the top layer is a glue (sticky) and/or colored layer. In a next step, as illustrated in FIG. 4C, holes 15 are made in the edges of the first foil 14 such as to correspond with the holes 13 in the jig 12. In a next step, as illustrated in FIG. 4D, light emitting devices in the form of a flexible substrate 6a, 6b, an array 2a, 2b of LED light sources 3a, 3b and an array 4a, 4b of optical elements 5a, 5b, are placed on the first foil 14 and jig 12. The light emitting devices may be held in place with a temporary glues or other fixation means just to hold the assembly together during the rest of the process. Now, in a following step as illustrated in FIG. 4E, a second foil 16 is vacuum formed onto the assembly obtained and illustrated in FIG. 4D by applying a vacuum from below (arrow 29). This will seal all the parts attached in the foregoing step and illustrated in FIG. 4D. Finally, as illustrated in FIG. 4G, the jig 12 is removed leaving a resulting sealed structure 30 and thus the final assembled light emitting device 100. The jig 12 may be used in successive production cycles.

It is noted that the first foil 14 may be reflective, such as white, and the second foil 16 may be transparent.

As may be seen in FIG. 4F, the resulting sealed structure 30 may further be provided with at least one, here two, first tracks 25 configured to receive the flexible substrate 6a, 6b on which the array 2a, 2b of LED light sources 3a, 3b are arranged, and a second track 26 configured to receive a driver in a manner described further below with respect to FIG. 14.

FIG. 5A-B shows additional steps of a method according to FIG. 4A-F. FIG. 5A-B illustrate that an additional element may be added, namely an air channel 18 for enhanced cooling properties of the array(s) of LED light sources 3a, 3b. The air channels are obtained by first, as illustrated in FIG. 5A, forming the jig 12 with additional slots 17. The slots 17 are provided with holes at bottom corners of the slots 17. Thereby, when the first foil 14 is vacuum formed onto the jig 12, the first foil 14 will be sucked into the slots 17 in the jig 12, thereby forming air channels 18. Now, when placed on the first foil 14, the arrays of LED light sources 3a, 3b, or more particularly the substrate 6a, 6b, closes off these channels 18 and prevents the second foil 16 from being sucked into the channels 18. When subsequently removing the jig 12 as shown in FIG. 5B, this leaves the channels 18 which are shaped by the first foil 14 and covered with the arrays of LED light sources 3a, 3b, or more particularly the substrate 6a, 6b. The channels 18 may be opened on both ends to make free air flow underneath the arrays of LED light sources 3a, 3b, which will enhance cooling.

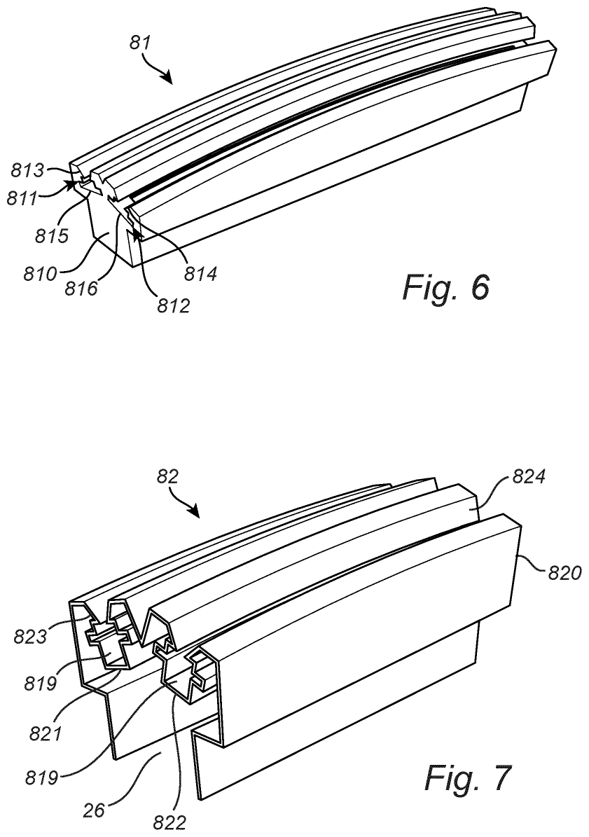

Turning now to FIGS. 6-8 two different solid holding devices 81 and 82 each having a structure different from that of the holding device 8 described above in relation to FIGS. 1 and 2 will be described.

FIG. 6 shows a perspective view of a solid holding device 81 of a light emitting device according to the invention. In this embodiment the solid holding device 81 is configured for allowing one or more light emitting devices in the form of a flexible substrate 6a, 6b, an array 2a, 2b of LED light sources 3a, 3b and an array 4a, 4b of optical elements 5a, 5b to be slid into place in the holding device 81 such as to form a light emitting device 1 of the type described in relation to FIG. 1 above. To this end the holding device 81 comprises one or more—in the embodiment shown two—channels 811 and 812 formed in a solid body 810. The channels 811 and 812 are configured to receive a substrate 6a, 6b on which an array 2a, 2b of LED light sources 3a, 3b and an array 4a, 4b of optical elements 5a, 5b are arranged. The channels 811, 812 thus correspond to the first track 24 described above in relation to FIG. 4F. In this embodiment the solid body 810 is a molded, 3D printed or cut element. Each channel 811, 812 comprises an opening 813, 814 extending upwards for allowing light emitting device light to be emitted. Each channel 811, 812 further comprises a bottom surface or support structure 815, 816 configured for abutment with the substrate 6a, 6b of a light emitting device in the assembled condition. Thereby, the flexible substrate 6a, 6b may be placed on the support structure 815, 816 in such a way that the flexible substrate 6a, 6b is in full surface contact with the support structure 815, 816.

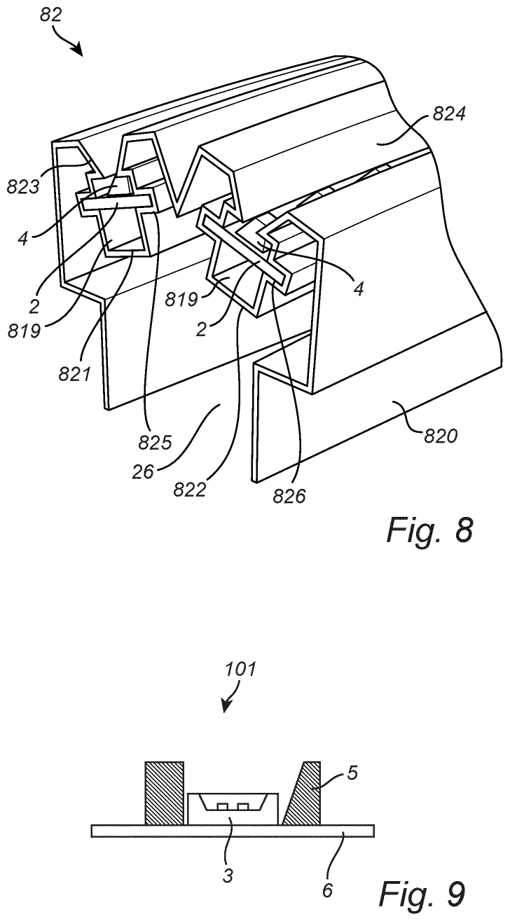

FIGS. 7 and 8 show perspective views of yet another solid holding device 82 of a light emitting device according to the invention without and with an array 2 of LED light sources 3 and an array 4 of optical elements 5 mounted thereon, respectively.

In this embodiment the solid holding device 82 is configured for allowing the light emitting device in the form of a flexible substrate 6a, 6b, an array 2a, 2b of LED light sources 3a, 3b and an array 4a, 4b of optical elements 5a, 5b to be slid into place in the holding device 82 in a position illustrated in FIG. 8 such as to form a light emitting device 1 of the type described in relation to FIG. 1 above. To this end the holding device 82 comprises one or more—in the embodiment shown two—channels 821 and 822 formed in a solid body 820. The solid body 820 may in this embodiment be formed, machined, molded or bent material or plate material. Each channel 821, 822 comprises an opening 823, 824 extending upwards for allowing light emitting device light to be emitted. Each channel 821, 822 further comprises a surface or support structure 825, 826 configured for abutment with a part of the substrate 6a, 6b of a light emitting device in the assembled condition. Thereby, the flexible substrate 6a, 6b may be placed on the support structure 825, 826 in such a way that the flexible substrate 6a, 6b is in partial surface contact with the support structure 825, 826 as is illustrated in FIG. 8.

The channels 821, 822 are configured to receive a substrate 6a, 6b on which an array 2 of LED light sources 3a, 3b and an array 4 of optical elements 5a, 5b are arranged. The channels 821, 822 of the solid holding device 82 thus correspond to the first track 24 described above in relation to FIG. 4F. The solid holding device 82 may further comprise a second track 26 configured to receive a driver in a manner described further below with reference to FIG. 14.

The solid holding device 82 further comprises an air channel 819 formed under the respective support structure 825, 826. In the assembled condition, the air channel 819 will thus be arranged underneath the flexible substrate 6a, 6b, and thus the array of LED light sources 3a, 3b, arranged in the channels 821, 822 of the holding device 82. Thereby the air channel 819 forms an element configured to enhance cooling of the LED light sources 3a, 3b of the light emitting device.

Generally, the holding device 8, 81, 81 and thus the support structure 815, 816, 825, 826 may be provided by any one of machining, molding, 3D printing, forming, bending, or by a pen arrangement connected to different parts of the substrate. It is noted that in the embodiment shown in FIG. 1, the support structure may be formed by either the upper surface of the holding device 8 or by the surface of the heat sink element 10a, 10b onto which the substrate 6a, 6b is attached.

In case of a sealed construction as described in relation to FIGS. 3-5B, the support structure may be formed by a section of the first foil 14. The support structure is in this case formed by a sealed construction (cf. FIG. 4A-4F), or by a sealed construction in combination with additional heat sink elements (cf. FIG. 5A-5B).

Turning now to FIGS. 9-11, a cross-sectional side view, a top view and a perspective view, respectively, of another light emitting device 101 according to the invention is shown.

The light emitting device 101 of FIGS. 9-11 differs mainly from those described above in relation to FIGS. 1-5 in that the array 4 of optical elements 5 is an array of micro-collimators 51-53. Thus, each LED light source 31-33 is associated with a micro-collimator 51-53. The micro-collimators 51-53 may be single collimators, with one collimator for each LED package 31-33, or they may be combined collimators, forming in that case a larger rigid area on the array 2 of LED light sources 31-33. In other words, each micro-collimator 51-53 of the array of micro-collimators may comprise a single micro-collimator or a combination of two or more micro-collimators.

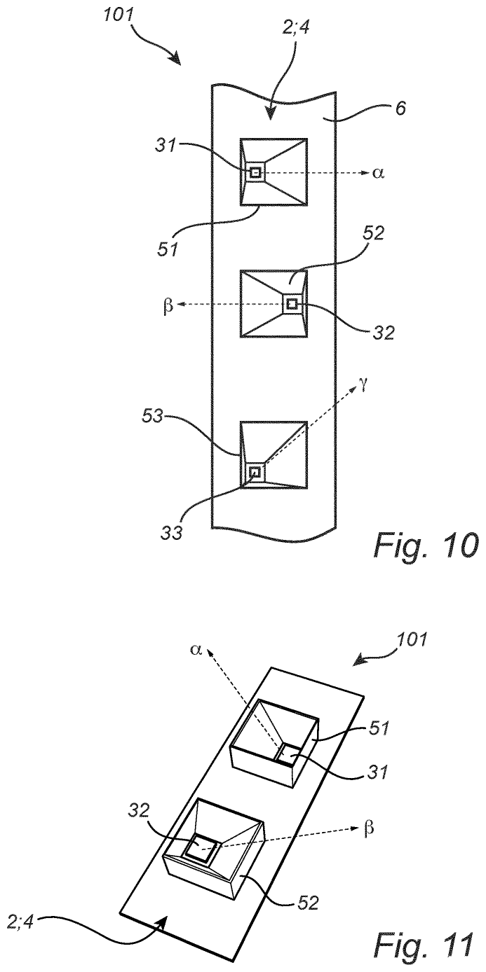

The use of micro-collimators 51-53 provides for an additional effect in that a further additional level of beam shaping from the individual LED packages or groups of LED sources can be achieved. More particularly, as illustrated on FIGS. 10 and 11, multiple optical axes can be achieved without the need to bend the array 2 of LED light sources 31-33. The multiple optical axes may be obtained by configuring the micro-collimators with individual optical axes or angles of emission a, B and y.

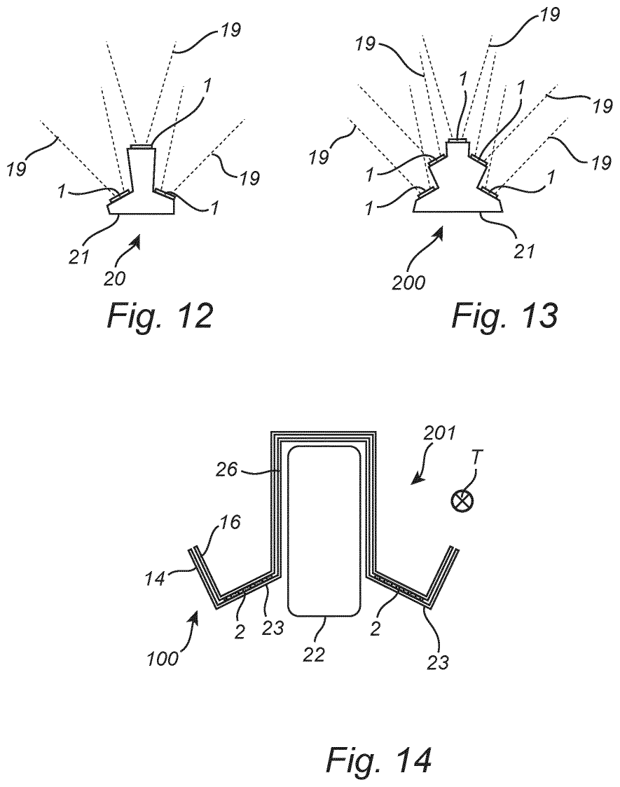

Turning now to FIGS. 12 and 13, cross-sectional side views of two different luminaires 20 and 200 comprising light emitting devices according to the invention are shown. The light emitting devices may in this connection be any light emitting device 1, 100, 101 according to the invention.

Generally, the luminaire 20, 200 may comprise a light emitting device with one single LED light source array 2, or the luminaire 20, 200 may comprise a light emitting device with a plurality of LED light source arrays 2a, 2b in different configurations.

FIG. 12 shows an embodiment in which the luminaire 20 comprises a mount 21 on which three light emitting devices 1 are arranged, each emitting a beam of light 19.

FIG. 13 shows an embodiment in which the luminaire 200 comprises a mount 21 on which five light emitting devices 1 are arranged, each emitting a beam of light 19.

Finally, FIG. 14 illustrates a cross-sectional side view of yet another luminaire 201 comprising light emitting devices according to the invention.

The luminaire 201 here comprises a light emitting device 100 and a track driver 22 arranged in a track 26 at the center of the light emitting device 100 and thus of the luminaire 201. The light emitting device 100 comprises arrays 2a, 2b of LED light sources 3a, 3b in a convex configuration on both sides. The luminaire 201 can light up specific areas along the axis T of the track 26. This minimizes the build height under the track 26 by using the space inside of the track 26. The light emitting device 100 of the luminaire 201 may comprise a double blister (vacuum form) construction, where the second foil 16 is transparent and the first foil 14 is reflective, for instance white.

Light emitting devices 1, 100, 101 according to the invention may be used in any suitable types of luminaires, including all lighting applications that require a specific light distribution. Applications include for instance creating low profile/low height ceiling luminaires and downlights as well as linear luminaires, troffers, and outdoor luminaires.

The person skilled in the art realizes that the present invention by no means is limited to the preferred embodiments described above. On the contrary, many modifications and variations are possible within the scope of the appended claims.

Additionally, variations to the disclosed embodiments can be understood and effected by the skilled person in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measured cannot be used to advantage.

1. A luminaire comprising at least one light emitting device adapted for, in operation, emitting light emitting device light, each of the at least one light emitting device comprising:
an array of LED light sources, where each LED light source of the array of LED light sources is adapted for, in operation, emitting LED light, and where each LED light source of the array of LED light sources comprises an LED package, and
an array of optical elements, where the array of optical elements is arranged such that each LED light source of the array of LED light sources is associated with an optical element of the array of optical elements, wherein
each optical element of the array of optical elements is configured to convert the LED light of the associated LED light source into a beam such that the combined LED light of the LED light sources of the array of LED light sources forming the light emitting device light forms a pixelated array, and wherein
each of the at least one light emitting devices further comprises a flexible substrate, the array of LED light sources being arranged on the flexible substrate, and the array of optical elements being arranged on the array of LED light sources,
wherein the LED light sources of the array of LED light sources are mechanically re-oriented by one or both of the following:
the flexible substrate is bent in a predetermined direction, and
one or more subsets of the LED light sources of the array of LED light sources are oriented in a predetermined direction,
such as to provide each of the at least one light emitting device light with a predetermined light pattern.

2. (canceled)

3. The luminaire according to claim 1, wherein one or more of the shape of the flexible substrate bent in a predetermined direction and the orientation of the LED light sources of the array of LED light sources in a predetermined direction is fixed by any one of:
foil fixation providing a sealed structure, and
a solid holding device configured to hold the substrate, the array of LED light sources and the array of optical elements.

4. The luminaire according to claim 2, wherein the sealed structure or the solid holding device further comprises one or more of:
at least one first track configured to receive the flexible substrate on which the array of LED light sources is arranged, and
a second track configured to receive a driver.

5. The luminaire according to claim 2, wherein the sealed structure or the solid holding device further comprises at least one first track configured to receive the flexible substrate on which the array of LED light sources is arranged, and a second track configured to receive a driver, and wherein the first track and the second track is arranged on mutually opposite sides of the sealed structure or the solid holding device.

6. The luminaire according to claim 2, wherein the sealed structure or the solid holding device further comprises on or more of:
one or more air channels, and
one or more heat sink elements
configured to provide cooling air to the LED light sources of the array of LED light sources.

7. The luminaire according to claim 2, wherein the sealed structure or the solid holding device further comprises a support structure, and wherein the flexible substrate is placed on the support structure in such a way that the flexible substrate is in full surface contact with the support structure.

8. The luminaire according to claim 2, wherein the foil fixation providing the sealed structure is provided by any one of:
sealing,
foil sealing,
vacuum forming, and
molding,
or wherein the solid holding device is provided by any one of:
machining,
molding,
3D printing, and
a pen arrangement connected to different parts of the substrate.

9. The luminaire according to claim 2, wherein the sealed structure comprises a first foil being reflective and a second foil being transparent, and wherein:
the first and the second foil each comprise a thickness being less than 0.5 mm, and/or
the first foil is provided with holes arranged in a predetermined pattern, the holes being provided before or during the foil sealing providing the sealed structure.

10. The luminaire according to claim 1, wherein the array of optical elements is an array of lenses.

11. The luminaire according to claim 9, wherein each lens of the array of lenses comprises a beam angle being in the interval of 30 to 60 degrees FWHM.

12. The luminaire according to claim 1, wherein the array of optical elements is an array of micro-collimators.

13. The luminaire according to claim 11, wherein each micro-collimator of the array of micro-collimators comprises a single micro-collimator or a combination of two or more micro-collimators.

14. (canceled)

15. The luminaire according to claim 1, wherein the at least one light emitting device comprises two light emitting devices, and wherein the luminaire further comprises a track driver arranged centrally between the two light emitting devices.
